(19) United States
(12) Patent Application Publication
(10) Pub. No.: US 2026/0012148 A1
(43) Pub. Date: Jan. 8, 2026

(54) AMPLIFYING CIRCUIT AND RF CIRCUIT INCLUDING THE SAME

(71) Applicant: SAMSUNG ELECTRONICS CO., LTD., SUWON-SI (KR)

(72) Inventors: Jongmin JEONG, Suwon-si (KR); Gwangchun PARK, Suwon-si (KR); Jongsoo LEE, Suwon-si (KR); Sangsung LEE, Suwon-si (KR); Sangmin YOO, Suwon-si (KR)

(21) Appl. No.: 19/008,779

(22) Filed: Jan. 3, 2025

(30) Foreign Application Priority Data
Jul. 2, 2024 (KR) 10-2024-0087019

(51) Int. Cl. H03F 3/45; H03F 1/32; H03F 3/195; H03F 3/217

(52) U.S. Cl. CPC H03F 3/45475; H03F 1/3211; H03F 3/195; H03F 3/217; H03F 3/45179; H03F 2200/129; H03F 2200/294; H03F 2200/451; H03F 2203/45138

(57) ABSTRACT

An amplifying circuit including: an amplifier configured to receive a first input voltage and a second input voltage, and output a first output voltage and a second output voltage by amplifying first input voltage and the second input voltage; and a common mode feedback circuit configured to receive the first output voltage through a first node and the second output voltage through a second node, and pull-down or pull-up a voltage level of the first node and a voltage level of the second node based on a magnitude of a feedback voltage based on a difference between a reference voltage and a common mode voltage determined from the first output voltage and the second output voltage.

This application claims priority under 35 U.S.C. § 119 to Korean Patent Application No. 10-2024-0087019 filed in the Korean Intellectual Property Office on Jul. 2, 2024, the disclosure of which is incorporated by reference herein in its entirety.

### TECHNICAL FIELD

The present disclosure relates to an amplifying circuit and an RF circuit including the same, and more particularly, to an amplifying circuit with enhanced stability and output voltage control.

### DISCUSSION OF RELATED ART

Generally, the DC level output common mode of an amplifier can be set to maximize the amplifier's output the swing range and gain. However, if the amplifier's bias voltage that establishes the common mode is fixed, the output signal range may become unstable or the gain may degrade due to factors such as changes in power, temperature, and process conditions, differences between the input common mode and the output common mode, or output common mode fluctuations caused by noise.

To ensure stable amplifier output, a feedback circuit may be incorporated at the amplifier's output. This circuit is referred to as a ‘common mode feedback circuit (CMFB)’.

### SUMMARY

The present disclosure provides an amplifying circuit with an expanded normal operation range and an RF circuit including the same.

The present disclosure provides an amplifying circuit with enhanced operational stability and an RF circuit including the same.

According to an embodiment of the present disclosure, there is provided an amplifying circuit including: an amplifier configured to receive a first input voltage and a second input voltage, and output a first output voltage and a second output voltage by amplifying the first input voltage and the second input voltage; and a common mode feedback circuit configured to receive the first output voltage through a first node and the second output voltage through a second node, and pull-down or pull-up a voltage level of the first node and a voltage level of the second node based on a magnitude of a feedback voltage based on a difference between a reference voltage and a common mode voltage determined from the first output voltage and the second output voltage.

According to an embodiment of the present disclosure, there is provided an amplifying circuit including: a first circuit configured to receive a first voltage through a first node, receive a second voltage through a second node, and output a common mode voltage based on the first voltage and the second voltage; a second circuit configured to generate a feedback voltage based on the common mode voltage and a reference voltage; and a third circuit connected to the first node and the second node, and configured to adjust levels of the first voltage and the second voltage based on the feedback voltage.

According to an embodiment of the present disclosure, there is provided an RF circuit including: a transmission filter configured to filter a first transmission signal input from an external device; a transmission mixer configured to receive the filtered first transmission signal, upconvert a frequency of the filtered first transmission signal, and output a second transmission signal; and a power amplifier configured to receive the second transmission signal, and amplify the second transmission signal, wherein the transmission filter includes an amplifier configured to receive the first transmission signal and a second signal whose phase is inverted from the first transmission signal, and output a first output signal and a second output signal by amplifying the first transmission signal and the second signal, and a common mode feedback circuit configured to receive the first output signal through a first node, receive the second output signal through a second node, generate a feedback current based on a reference voltage and a common mode voltage that is based on the first output signal and the second output signal, and adjust a voltage level of the first node and a voltage level of the second node according to the feedback current.

### BRIEF DESCRIPTION OF THE DRAWINGS

A brief description of each drawing is provided below to facilitate a better understanding of the figures referenced in the detailed description of the present disclosure.

FIG. 1 is a block diagram showing a communication device according to an embodiment.

FIG. 2 is a circuit diagram of a filter including an amplifying circuit according to an embodiment.

FIG. 3 is a circuit diagram of an amplifying circuit according to an embodiment.

FIG. 4 is a circuit diagram of a common mode feedback circuit according to an embodiment.

FIG. 5 is a circuit diagram of a common mode feedback circuit according to an embodiment.

FIG. 6 is a circuit diagram of a common mode feedback circuit according to an embodiment.

FIG. 7 is a circuit diagram of an amplifying circuit according to an embodiment.

FIG. 8 is a circuit diagram of an additional amplifying circuit according to an embodiment.

FIG. 9 is a circuit diagram of an additional amplifying circuit according to an embodiment.

FIG. 10 is a circuit diagram of a filter including an amplifying circuit according to an embodiment.

FIG. 11 is a graph showing a change in gain of a negative feedback loop according to an embodiment.

FIG. 12 is a block diagram showing a communication device according to an embodiment.

FIG. 13 is a block diagram showing a mobile terminal to which a communication device according to an embodiment is applied.

### DETAILED DESCRIPTION OF THE EMBODIMENTS

The present disclosure will be described in detail below with reference to the accompanying drawings, which illustrate embodiments of the disclosure. It should be understood by those skilled in the art that these embodiments may be modified in various different ways without departing from the spirit or scope of the present disclosure.

To clearly illustrate the present disclosure, elements unrelated to the description are omitted from the drawings, and like numerals indicate similar or identical elements throughout the specification. The sequence of operations or steps is not limited to the order presented in the claims or figures. Operations or steps may be reordered, combined, divided, or omitted as appropriate.

In addition, unless explicitly stated with terms like “one” or “single,” singular forms may also encompass plural forms. Terms such as “first,” “second,” and similar ordinal numbers are used solely to describe various components and should not be construed as limiting. These terms may be used to distinguish one component from another.

The present disclosure addresses instability issues in prior art amplifying circuits, specifically regarding a common mode feedback circuit (CMFB). In the prior art, the CMFB adjusts the output stage common mode voltage (VCMO) of an amplifier but struggles when the current in the pull-up path approaches zero, causing the output stage to float and resulting in malfunction.

The present disclosure introduces a pull-down path to complement the pull-up path. This pull-down path reduces the output voltage level when the VCMO is higher than a reference voltage, increasing the current magnitude of the pull-down path based on comparison results between VCMO and the reference voltage. Additionally, the CMFB connects directly to the output voltage node and integrates with a two-stage amplification circuit, enhancing stability and control over the output voltage.

In summary, the present disclosure improves the stability and operational reliability of amplifying circuits by incorporating a pull-down path for more effective output voltage regulation.

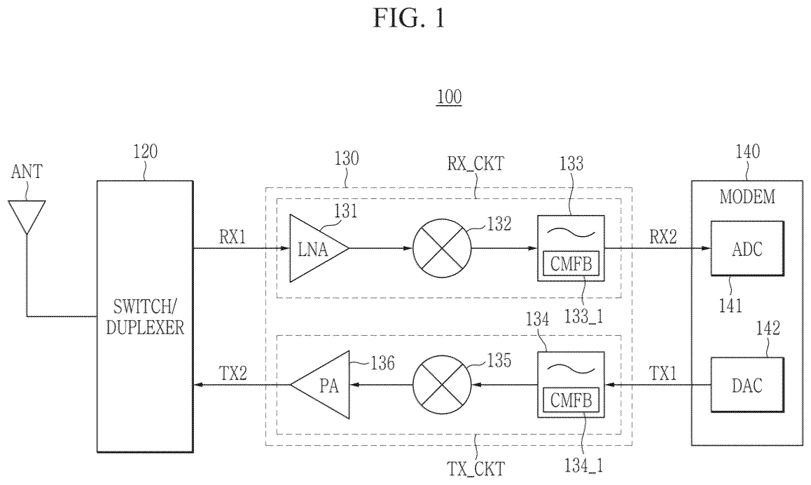

FIG. 1 is a block diagram showing a communication device according to an embodiment.

Referring to FIG. 1, a communication device 100 may connect to a wireless communication system by transmitting and receiving signals through an antenna ANT. Wireless communication systems that can be connected by the communication device 100 may be referred to as radio access technologies (RATs). These may include cellular networks such as next generation wireless systems, 5G (5th generation) wireless systems, long term evolution (LTE) wireless systems, LTE-Advanced systems, code-division multiple access (CDMA) wireless systems, global system for mobile communications (GSM) systems. They may also include wireless local area networks (WLANs) or other wireless communication systems. Hereinafter, the wireless communication system connected to the communication device 100 is assumed to use a cellular network. However, embodiments of the present disclosure is not limited thereto.

The wireless communication network of the wireless communication system may share available network resources, and thereby enable a plurality of wireless communication devices including the communication device 100 to communicate with each other. For example, in the wireless communication network, information may be transferred in various multiple access methods such as code-division multiple access (CDMA), frequency-division multiple access (FDMA), time-division multiple access (TDMA), orthogonal frequency-division multiple access (OFDMA), single-carrier frequency-division multiple access (SC-FDMA), OFDM-FDMA, OFDM-TDMA, and OFDM-CDMA.

The communication device 100 may refer to any device connecting to the wireless communication system. As an example of the communication device 100, a base station may generally refer to a fixed station that communicates with user equipment and/or other base stations. The base station may exchange data and control information by communicating with user equipment and/or other base stations. For example, the base station may be referred to as a Node B, evolved-Node B (eNB), next generation Node B (gNB), sector, site, base transceiver system (BTS), access point (AP), relay node, remote radio head (RRH), radio unit (RU), small cell, or the like. Here, the base station or cell may be understood to represent an area or functionality that includes the base station controller (BSC) in CDMA, Node-B in WCDMA, eNB or sector (site) in LTE. Additionally, it may encompass various coverage areas such as megacells, macrocells, microcells, picocells, femtocells, as well as the communication range of relay nodes, RRHs, RUs, and small cells.

As an example of the communication device 100, the user equipment (UE) may be fixed or have mobility, and may refer to any device that can transmit and receive data and/or control information by communicating the base station. For example, the user equipment may be referred to as a terminal equipment, a mobile station (MS), a mobile terminal (MT), a user terminal (UT), a subscribe station (SS), a wireless device, a handheld device, or the like. Here, the communication device 100 is assumed to be the user equipment UE, but the present disclosure is not limited thereto.

The communication device 100 may include a switch/duplexer 120, a transceiver 130, and a modem 140. The switch/duplexer 120 may provide signals received through an antenna ANT to the transceiver 130 as a first received signal RX1, and may provide a second transmission signal TX2 received from the transceiver 130 to the antenna ANT.

The transceiver 130 may include a receiver circuit RX_CKT (also referred to as a receiver) and a transmitter circuit TX_CKT (also referred to as a transmitter).

The receiver circuit RX_CKT may process the first received signal RX1 received from the switch/duplexer 120 to generate a second received signal RX2, and provide the second received signal RX2 to the modem 140. The receiver circuit RX_CKT may include a low noise amplifier (LNA) 131, a RX mixer 132, and a RX filter 133 to process the first received signal RX1. The low noise amplifier 131 may amplify its input signal to generate an output signal, and the RX mixer 132 may perform a frequency down-conversion on its input signal in a first radio frequency (RF) band to generate an output signal in the baseband. The RX filter 133 may remove undesired portions from its input signal, thereby generating the second received signal RX2.

The transmitter circuit TX_CKT may process a first transmission signal TX1 received from the modem 140 to generate the second transmission signal TX2, and provide the second transmission signal TX2 to the switch/duplexer 120. The transmitter circuit TX_CKT may include a TX filter 134, a TX mixer 135, and power amplifier (PA) 136 to process the first transmission signal TX1. The TX filter 134 may filter the first transmission signal TX1 received from the modem 140, and may provide the filtered signal to the TX mixer 135. The TX mixer 135 may perform a frequency up-conversion with respect to the signal received from the TX filter 134 to generate an output signal in a second RF band, and the power amplifier 136 may amplify the input signal to generate the second transmission signal TX2.

In an embodiment, the RX filter 133 and the TX filter 134 may include an amplifier. The output signal range of the amplifier within the RX filter 133 and the TX filter 134 can vary due to several factors. For example, input signals exceeding expected levels may be input into the RX filter 133 and the TX filter 134, or noise-induced changes in the common mode output voltage of the amplifier may alter the amplifier's output signal range. As such, the common mode output voltage of the amplifier within the RX filter 133 and the TX filter 134 may shift from a predetermined level (e.g., a midpoint between the supply voltage and the ground voltage), thereby limiting the operation of the amplifier.

To adjust the level of the common mode output voltage, the RX filter 133 and the TX filter 134 may include common mode feedback circuits (CMFB) 133_1 and 134_1, respectively. The common mode feedback circuits 133_1 and 134_1 may operate as negative feedback circuits to detect the common mode output voltage of the amplifier within the RX filter 133 and the TX filter 134, compare the detected common mode output voltage to a reference voltage, and modify the detected common mode output voltage to align with (or become close to) the reference voltage based on the comparison. When the common mode output voltage is higher than the reference voltage, the common mode feedback circuits 133_1 and 134_1 may use a pull-down circuit included therein to lower the voltage level of the common mode output voltage. Conversely, when the common mode output voltage is lower than the reference voltage, the common mode feedback circuits 133_1 and 134_1 may use a pull-up circuit included therein to raise the voltage level of the common mode output voltage. Although described here for amplifiers within the RX filter 133 and the TX filter 134, this approach is not limited to these components; it may also be applied to the low noise amplifier 131 and a power amplifier 138.

The modem 140 may process the first transmission signal TX1, which contains information to be transmitted, according to a preset communication scheme. In addition, the modem 140 may process the received second received signal RX2 according to a preset communication method. For example, the modem 140 may process the transmitted or received signal according to a communication scheme such as OFDM OFDMA, WCDMA, HSPA+, or the like. In addition, the modem 140 may process the first transmission signal TX1 and the second received signal RX2 according to various types of communication schemes. In other words, various communication schemes may apply the technique of modulating or demodulating the amplitude and/or frequency of the first transmission signal TX1 and the second received signal RX2. The modem 140 may include an analog/digital converter (ADC) 141 and a digital/analog converter (DAC) 142.

The ADC 141 may convert the second received signal RX2 into a digital signal and output the converted signal. Information may be extracted from the output digital signal by a digital processing such as filtering, demodulation, decoding, or the like.

The DAC 142 may convert the digital signal to transmit to the first transmission signal TX1, which is an analog signal. The DAC 142 may generate the first transmission signal TX1 through a digital processing of information such as filtering, modulation, encoding, or the like, and may output the first transmission signal TX1.

The configuration of the communication device 100 shown in FIG. 1 is provided as an example embodiment. The communication device 100 is not limited to this arrangement, and may vary depending on the communication protocol or communication scheme.

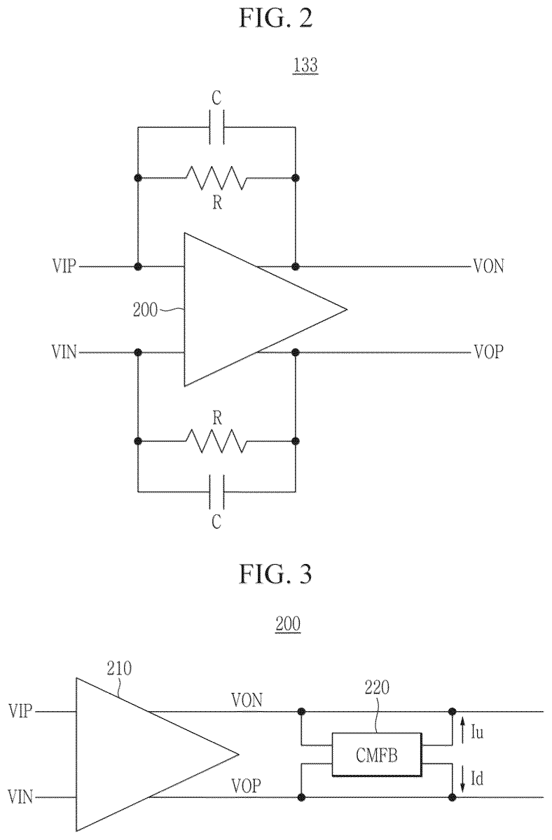

FIG. 2 is a circuit diagram of a filter including an amplifying circuit according to an embodiment. Here, for better understanding and ease of description, the RX filter 133 is illustrated, but the TX filter 134 (see FIG. 1) may also include the same or similar configuration.

Referring to FIG. 2, the RX filter 133 may include an amplifying circuit 200 that receives input voltages VIP and VIN, and a feedback resistor R and a feedback capacitor C connected in parallel to an input end and an output end of the amplifying circuit 200.

The amplifying circuit 200 may receive the input voltages VIP and VIN as input signals, and amplify them to produce output voltages VOP and VON as output signals. The gain and cutoff frequency of the RX filter 133 may be determined according to a resistance value of the feedback resistor R and a capacitance of the feedback capacitor C. For example, cutoff frequency of the RX filter 133 may may be inversely proportional to the resistance value of the feedback resistor R and the capacitance of the feedback capacitor C. In an embodiment, the feedback resistor R and the feedback capacitor C may be a variable resistor and a variable capacitor. The internal structure of the amplifying circuit 200 will be described later with reference to FIG. 3 to FIG. 7.

FIG. 3 is a circuit diagram of an amplifying circuit according to an embodiment.

In an embodiment, the amplifying circuit 200 may include an amplifier 210 and a common mode feedback circuit 220. The amplifier 210 may receive a first input voltage VIP and a second input voltage VIN, and may output a first output voltage VOP and a second output voltage VON by amplifying the first input voltage VIP and the second input voltage VIN. In an embodiment, the first input voltage VIP and the second input voltage VIN may be differential signals having opposite phases. In addition, the amplifier 210 may be an inverting amplifier that inverts the phase of its input signal.

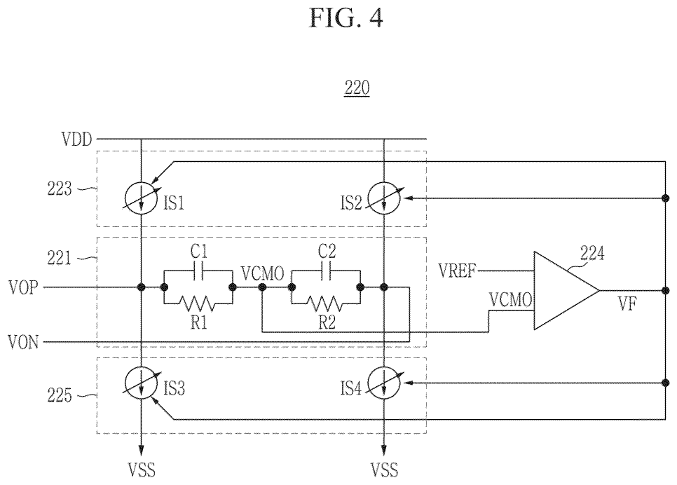

In an embodiment, the common mode feedback circuit 220 may receive the first output voltage VOP and the second output voltage VON, and may adjust these voltages based on the difference between the voltage of the first output voltage VOP and the second output voltage VON and a reference voltage. For example, the common mode feedback circuit 220 may generate feedback currents Iu and Id to adjust the first output voltage VOP and the second output voltage VON such that the average voltage of the first output voltage VOP and the second output voltage VON becomes approximately equal to the reference voltage. Here, the feedback currents Iu and Id may act as pull-up or pull-down currents. For example, if the average level of the first output voltage VOP and the second output voltage VON is higher than the level of the reference voltage, the common mode feedback circuit 220 may increase the feedback currents Iu and Id to pull-down the first output voltage VOP and the second output voltage VON, thereby lowering the voltage levels of the first output voltage VOP and the second output voltage VON. Alternatively, if the average level of the first output voltage VOP and the second output voltage VON is lower than the level of the reference voltage, the common mode feedback circuit 220 may increase the feedback currents Iu and Id to pull-up the first output voltage VOP and the second output voltage VON, thereby raising the voltage levels of the first output voltage VOP and the second output voltage VON. This way, the common mode feedback circuit 220 stabilizes the common mode output voltage to match a reference, ensuring reliable performance and balanced signal levels. In addition, the common mode feedback circuit 220 adjusts dynamically to prevent errors and maintain optimal operation in varying conditions. Detailed description on the common mode feedback circuit 220 will be described later with reference to FIG. 4.

FIG. 4 is a circuit diagram of a common mode feedback circuit according to an embodiment.

In an embodiment, the common mode feedback circuit 220 may include a common mode voltage output circuit 221, a pull-up circuit 223, a pull-down circuit 225, and an amplifier 224.

In an embodiment, the common mode voltage output circuit 221 may output a common mode output voltage VCMO, based on the first output voltage VOP and the second output voltage VON. In an embodiment, the common mode output voltage VCMO may correspond to an average value of the first output voltage VOP and the second output voltage VON. The common mode voltage output circuit 221 may include a first resistor R1 and a first capacitor C1 coupled in parallel, and a second resistor R2 and a second capacitor C2 coupled in parallel. In an embodiment, the common mode output voltage VCMO may include an averaged value of the first output voltage VOP and the second output voltage VON obtained based on the impedance value of the first resistor R1 and the first capacitor C1 and the impedance value of the second resistor R2 and the second capacitor C2.

In an embodiment, the amplifier 224 may receive the common mode output voltage VCMO from the common mode voltage output circuit 221, and may generate a feedback voltage VF to adjust the first output voltage VOP and the second output voltage VON based on the common mode output voltage VCMO and a reference voltage VREF.

In an embodiment, the pull-up circuit 223 may include a first variable current source IS1 and a second variable current source IS2. The first variable current source IS1 may be connected between a supply voltage VDD line and the first output voltage VOP node, and the second variable current source IS2 may be connected between the supply voltage VDD line and the second output voltage VON node. The pull-up circuit 223 may pull-up the voltage levels of the first output voltage VOP and the second output voltage VON such that the common mode output voltage VCMO reaches a first voltage level based on the feedback voltage VF. For example, if the common mode output voltage VCMO is lower than the reference voltage VREF, the pull-up currents from the first variable current source IS1 and the second variable current source IS2 may increase based on the feedback voltage VF received from the amplifier 224. Consequently, the voltage levels of the first output voltage VOP and the second output voltage VON are pulled-up bringing the common mode output voltage VCMO to the first voltage level. Here, the first voltage level may correspond to the voltage level of the reference voltage VREF, but is not limited thereto.

In an embodiment, the pull-down circuit 225 may include a third variable current source IS3 and a fourth variable current source IS4. The third variable current source IS3 may be connected between the first output voltage VOP node and a ground voltage VSS line, and the fourth variable current source IS4 may be connected between the second output voltage VON node and the ground voltage VSS line. The pull-down circuit 225 may pull-down the first output voltage VOP and the second output voltage VON such that the common mode output voltage VCMO reaches a second voltage level based on the feedback voltage VF. For example, if the common mode output voltage VCMO is higher than the reference voltage VREF, the pull-down currents from the third variable current source IS3 and the fourth variable current source IS4 may increase based on the feedback voltage VF received from the amplifier 224. As a result, the voltage levels of the first output voltage VOP and the second output voltage VON may be pulled-down bringing the common mode output voltage VCMO to the second voltage level. Here, the second voltage level may correspond to the voltage level of the reference voltage VREF, but is not limited thereto.

The common mode feedback circuit 220 according to an embodiment may adjust the levels of the first output voltage VOP and the second output voltage VON by either pulling them up or down. This adjustment is based on to the magnitude of a feedback voltage VF, which is derived from a difference between the reference voltage VREF and the common mode output voltage VCMO, where the common mode output voltage VCMO is determined from the first output voltage VOP and the second output voltage VON.

The common mode feedback circuit 220 according to an embodiment may increase the range of the common mode output voltage VCMO within which the amplifying circuit 200 (see FIG. 3) can normally operate. Specifically, the common mode feedback circuit 220 may compare the reference voltage with the output voltages VOP and VON. Based on this comparison, the common mode feedback circuit 220 may increase the voltage levels of the output voltages VOP and VON by using the pull-up circuit 223, or decrease the voltage levels of the output voltages VOP and VON by using the pull-down circuit 225. By adjusting the voltage levels of the output voltages VOP and VON within a preset range, the common mode feedback circuit 220 can enlarge the operating range of the common mode output voltage VCMO in which the amplifying circuit 200 can operate normally, thereby enhancing the stability of the amplifying circuit 200.

The common mode feedback circuit 220 shown in FIG. 4 is merely an example embodiment, and the circuit structure of the common mode feedback circuit 220 is not limited thereto. For example, the pull-up circuit 223 and the pull-down circuit 225 of the common mode feedback circuit 220 according to an embodiment may each include a current source. These current sources may simultaneously adjust voltage levels of the first output voltage VOP node and the second output voltage VON node. For example, the pull-up circuit 223 may include a current source connected between a power source voltage VDD line and the first output voltage VOP node and the second output voltage VON node. In addition, the pull-down circuit 225 may include a current source connected between the first output voltage VOP node and the second output voltage VON node and the ground voltage VSS node. Each current source may adjust the voltage levels of the first output voltage VOP and the second output voltage VON based on the feedback voltage VF.

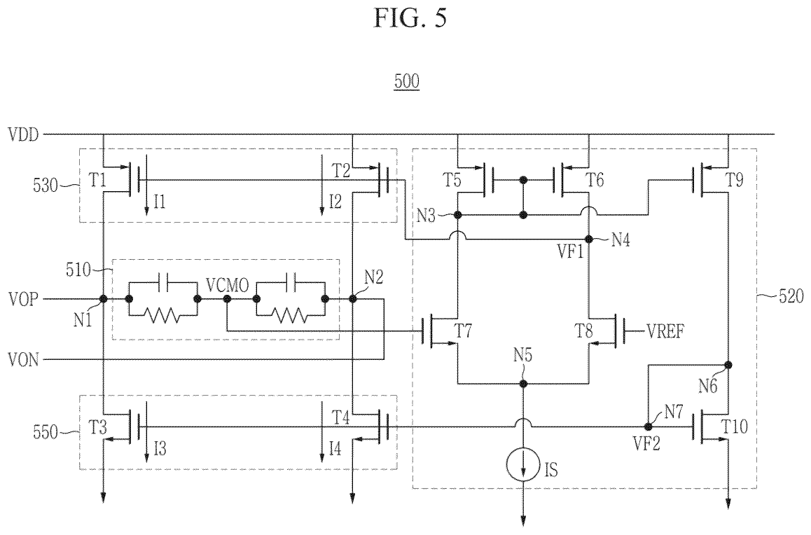

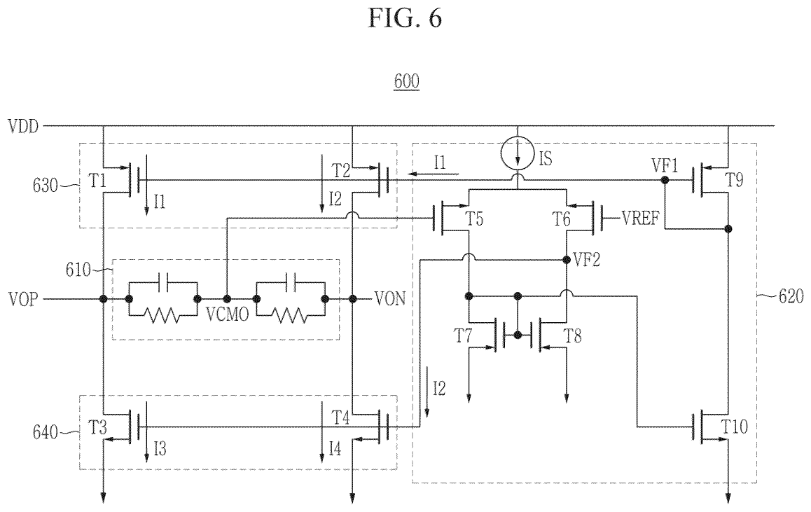

FIG. 5 and FIG. 6 is a circuit diagram of a common mode feedback circuit according to an embodiment. Descriptions that are the same as or similar to the above description made with reference to FIG. 4 may be omitted.

In an embodiment, a common mode feedback circuit 500 may include a common mode voltage output circuit 510, a pull-up circuit 530, a pull-down circuit 550, and an amplifier 520.

In an embodiment, the pull-up circuit 530 may include a first transistor T1 and a second transistor T2. The first transistor T1 may be connected between the supply voltage VDD line and a node N1. Specifically, the source and drain of the first transistor T1 may be connected to the supply voltage VDD line and the node N1, respectively. The first transistor T1 may receive a voltage of a node N4 as a first feedback voltage VF1 through its gate. The first transistor T1 may transfer a current I1 flowing through its source and drain to the node N1 based on the first feedback voltage VF1. Here, the first feedback voltage VF1 may refer to the feedback voltage VF of FIG. 4.

The second transistor T2 may be connected between the supply voltage VDD line and a node N2. Specifically, the source and drain of the second transistor T2 may be connected to the supply voltage VDD line and the node N2, respectively. The second transistor T2 may receive the voltage of the node N4 as the first feedback voltage VF1 through its gate. The second transistor T2 may transfer a current I2 flowing through its source and drain to the node N2 based on the first feedback voltage VF1. The current I1 and the current I2 may be the same as or different from each other. The first transistor T1 and the second transistor T2 may be turned-on according to a level of the first feedback voltage VF1, to supply the currents I1 and I2 to the nodes N1 and N2 as the feedback currents Iu and Id (see FIG. 3). The first transistor T1 and the second transistor T2 may be turned-on according to the level of the first feedback voltage VF1, to pull-up the voltage levels of the first output voltage VOP and the second output voltage VON, such that the common mode output voltage VCMO reaches the first voltage level (e.g., the reference voltage level). The currents I1 and I2 may be a pull-up current.

In an embodiment, the pull-down circuit 550 may include a third transistor T3 and a fourth transistor T4. The third transistor T3 may be connected between the node N1 and the ground voltage VSS line. Specifically, the source and drain of the third transistor T3 may be connected to the node N1 and the ground voltage VSS line, respectively. The third transistor T3 may receive a voltage of a node N7 as a second feedback voltage VF2 through its gate. The third transistor T3 may enable a current I3 to flow through its source and drain based on the second feedback voltage VF2. Here, the second feedback voltage VF2 may refer to the feedback voltage VF of FIG. 4. The fourth transistor T4 may be connected between the node N2 and the ground voltage VSS line. Specifically, the source and drain of the fourth transistor T4 may be connected to the node N2 and the ground voltage VSS line, respectively. The fourth transistor T4 may receive the voltage of the node N7 as the second feedback voltage VF2 through its gate. The fourth transistor T4 may enable a current I4 to flow through its source and drain based on the second feedback voltage VF2. The current I3 and the current I4 may be the same as or different from each other. The third transistor T3 and the fourth transistor T4 may be turned-on according to the level of the second feedback voltage VF2, to supply the currents I3 and I4 to the nodes N1 and N2 as the feedback currents Iu and Id (see FIG. 3). The third transistor T3 and the fourth transistor T4 may be turned-on according to the level of the second feedback voltage VF2, to pull-down the voltage levels of the first output voltage VOP and the second output voltage VOP, such that the common mode output voltage VCMO reaches the second voltage level (e.g., the reference voltage level). The currents I3 and I4 may be a pull-down current.

In an embodiment, the amplifier 520 may include a fifth transistor T5, a sixth transistor T6, a seventh transistor T7, an eighth transistor T8, a ninth transistor T9, a tenth transistor T10, and the current source IS. The fifth transistor T5 may be connected between the supply voltage VDD line and a node N3. Specifically, the source and drain of the fifth transistor T5 may be connected to the supply voltage VDD line and the node N3, respectively. A gate of the fifth transistor T5 may be connected to the node N3. The gate of the fifth transistor T5 may be connected to a gate of the sixth transistor T6 and a gate of the ninth transistor T9. The sixth transistor T6 may be connected between the supply voltage VDD line and the node N4. Specifically, the source and drain of the sixth transistor T6 may be connected to the supply voltage VDD line and the node N4, respectively. The gate of the sixth transistor T6 may be connected to the node N3. The seventh transistor T7 may be connected between the node N3 and a node N5. Specifically, the source and drain of the seventh transistor T7 may be connected to the node N3 and the node N5, respectively. The seventh transistor T7 may receive the common mode output voltage VCMO through its gate. The seventh transistor T7 may be turned-on according to the voltage level of the common mode output voltage VCMO. The eighth transistor T8 may be connected between the node N4 and the node N5. Specifically, the source and drain of the eighth transistor T8 may be connected to the node N4 and the node N5, respectively. The eighth transistor T8 may receive the reference voltage VREF through its gate. The eighth transistor T8 may be turned-on according to the voltage level of the reference voltage VREF. The current source IS may be connected between the node N5 and the ground voltage VSS line. The ninth transistor T9 may be connected between the supply voltage VDD line and a node N6. Specifically, the source and drain of the ninth transistor T9 may be connected to the supply voltage VDD line and the node N6, respectively. The gate of the ninth transistor T9 may be connected to the node N3. The tenth transistor T10 may be connected between the node N6 and the ground voltage VSS line. Specifically, the source and drain of the tenth transistor T10 may be connected to the node N6 and the ground voltage VSS line, respectively. A gate of the tenth transistor T10 may be connected to the node N7.

In an embodiment, the first transistor T1, the second transistor T2, the fifth transistor T5, the sixth transistor T6, and the ninth transistor T9 may be implemented as a P-type transistor, and the third transistor T3, the fourth transistor T4, the seventh transistor T7, the eighth transistor T8, and the tenth transistor T10 may be implemented as a N-type transistor, but are not limited thereto.

In the operation of the common mode feedback circuit 500, when the common mode output voltage VCMO falls below the reference voltage VREF, the turn-on level of the seventh transistor T7 decreases, causing a voltage of the node N3 to rise. As the voltage of the node N3 increases, the turn-on levels of the fifth transistor T5 and the sixth transistor T6 decrease. Specifically, the reduced gate-source voltages of the fifth transistor T5 and the sixth transistor T6 reduce the current flowing through the fifth transistor T5 and the sixth transistor T6 along the supply voltage VDD line, causing the voltage of the node N4 to drop. The voltage of the node N4, referred to as the first feedback voltage VF1, is transferred to the first transistor T1 and the second transistor T2. As the first feedback voltage VF1 decreases, the turn-on levels of the first transistor T1 and the second transistor T2 increase. This, in turn, raises the gate-source voltages of the first transistor T1 and the second transistor T2, increasing the current I1 flowing through the first transistor T1 at the node N1 and the current I2 flowing through the second transistor T2 at the node N2 along the supply voltage VDD line. Therefore, the voltages of the node N1 and the node N2 increase, resulting in an increase in the voltage levels of the first output voltage VOP and the second output voltage VON. Therefore, the common mode output voltage VCMO is pulled-up to the first voltage level (e.g., the reference voltage VREF). Meanwhile, as the voltage at the node N3 rises, a turn-on level of the ninth transistor T9 decreases, causing a voltage at the node N6 to drop. Specifically, the reduced gate-source voltage of the ninth transistor T9 decreases the current flowing through the ninth transistor T9 along the supply voltage VDD line. This, in turn, reduces the turn-on levels of the third transistor T3 and the fourth transistor T4, effectively blocking the pull-down path for pulling-down the voltage levels of the first output voltage VOP and the second output voltage VON.

In an embodiment, when the common mode output voltage VCMO exceeds the reference voltage VREF, the turn-on level of the seventh transistor T7 increases. Accordingly, current flowing through the fifth transistor T5 is directed through the node N3 and the seventh transistor T7, causing the voltage of the node N3 to decrease. When the voltage at the node N3 decreases, the turn-on levels of the fifth transistor T5 and the sixth transistor T6 increase, leading to an increase in the voltage at the node N4. As the voltage at the node N4 rises, the turn-on levels of the first transistor T1 and the second transistor T2 decrease. This reduction decreases the currents I1 and I2 flowing through the first transistor T1 and the second transistor T2, respectively, effectively blocking the pull-up path for pulling-up the voltage levels of the first output voltage VOP and the second output voltage VON. Meanwhile, as the voltage at the node N3 decreases, the turn-on level of the ninth transistor T9 increases. Specifically, of the decrease in the node's N3 voltage raises the gate-source voltage of the ninth transistor T9, increasing the current flowing through the ninth transistor T9 along the supply voltage VDD line. Therefore, the voltages at the node N6 and the node N7 increase. The voltage at the node N7, referred to as the second feedback voltage VF2, is transferred to the third transistor T3 and the fourth transistor T4. As the second feedback voltage VF2 increases, the turn-on levels of the third transistor T3 and the fourth transistor T4 also increase. Specifically, the increased gate-source voltages of the third transistor T3 and the fourth transistor T4 raise the current I3 flowing from the node N1 to the ground voltage VSS line through the third transistor T3, and the current I4 flowing from the node N2 to the ground voltage VSS line through the fourth transistor T4. Therefore, the voltages at the node N1 and the node N2 decrease, leading to a reduction in the voltage levels of the first output voltage VOP and the second output voltage VON. Therefore, the common mode output voltage VCMO is pulled-down to the second voltage level (e.g., the reference voltage VREF).

However, the circuit diagram of the common mode feedback circuit 500 is not limited thereto. Referring to FIG. 6, a common mode feedback circuit 600 according to an embodiment may include a common mode voltage output circuit 610, a pull-up circuit 630, a pull-down circuit 640, and an amplifier 620. Unlike FIG. 5, the current source IS within the amplifier 620 according to an embodiment may be connected to the supply voltage VDD line, and the transistors T5 and T6 that receive the common mode output voltage VCMO and the reference voltage VREF may be connected to the current source IS and implemented as P-type transistors. An operation method of the common mode feedback circuit 600 may be similar to the operation method of the common mode feedback circuit 500 illustrated in FIG. 5. As such, the common mode feedback circuit the present disclosure may be implemented in various structures.

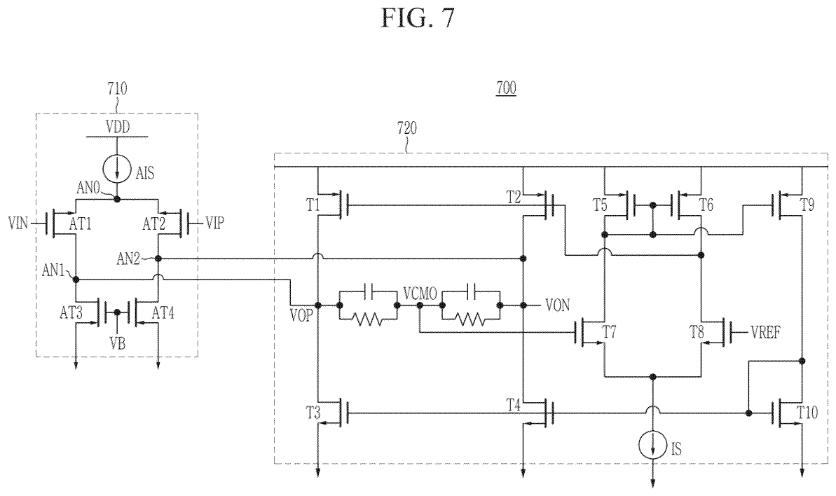

FIG. 7 is a circuit diagram of an amplifying circuit according to an embodiment. For convenience of description, descriptions that are the same as or similar to FIG. 4 to FIG. 6 may be omitted. In addition, the circuit diagram of the amplifying circuit of FIG. 7 is merely an example embodiment, and the circuit diagram of the amplifying circuit is not limited thereto.

In an embodiment, an amplifying circuit 700 may include an amplifier 710 and a common mode feedback circuit 720. Here, the common mode feedback circuit 720 as illustrated has the same structure as the circuit diagram of FIG. 5; however, the structure of the common mode feedback circuit 720 is not limited thereto.

Referring to FIG. 7, the amplifier 710 may include a first transistor AT1, a second transistor AT2, a third transistor AT3, a fourth transistor AT4, and a current source AIS. In an embodiment, the current source AIS may be connected between the supply voltage VDD line and a node AN0. In addition, the first transistor AT1 may be connected between the node AN0 and a node AN1. Specifically, the source and drain of the first transistor AT1 may be connected to the node AN0 and the node AN1, respectively. The first transistor AT1 may receive a first input voltage VIN through its gate. The second transistor AT2 may be connected between the node AN0 and a node AN2. Specifically, the source and drain of the second transistor AT2 may be connected to the node AN0 and the node AN2, respectively. The second transistor AT2 may receive a second input voltage VIP through its gate. The third transistor AT3 may be connected between the node AN1 and the ground voltage VSS line. Specifically, the source and drain of the third transistor AT3 may be connected to the node AN1 and the ground voltage VSS line, respectively. The fourth transistor AT4 may be connected between the node AN2 and the ground voltage VSS line. Specifically, the source and drain of the fourth transistor AT4 may be connected to the node AN2 and the ground voltage VSS line, respectively. The third transistor AT3 and the fourth transistor AT4 may receive bias voltage (VB) through their gates.

In an embodiment, the first transistor AT1 may receive the first input voltage VIN through its gate, and may adjust the current flowing through the node AN1 in the current source AIS based on the first input voltage VIN. The second transistor AT2 may receive the second input voltage VIP through its gate, and may adjust the current flowing through the node AN2 in the current source AIS based on the second input voltage VIP. The node AN1 and the node AN2 may be an output end of an amplifier 610. In other words, a voltage level of the node AN1 may be output to the common mode feedback circuit 720 as the first output voltage VOP, and a voltage level of the node AN2 may be output to the common mode feedback circuit 720 as the second output voltage VON.

In an embodiment, the first transistor AT1 and the second transistor AT2 may be implemented as a P-type transistor, and the third transistor AT3 and the fourth transistor AT4 may be implemented as a N-type transistor, but is not limited thereto.

As described above, the common mode feedback circuit 720 may generate the common mode output voltage VCMO based on the first output voltage VOP and the second output voltage VON received from the amplifier 710. The common mode feedback circuit 720 may then adjust the voltage levels of the first output voltage VOP and the second output voltage VON to ensure that the common mode output voltage VCMO corresponds to the reference voltage VREF, based on the comparison between the common mode output voltage VCMO and the reference voltage VREF.

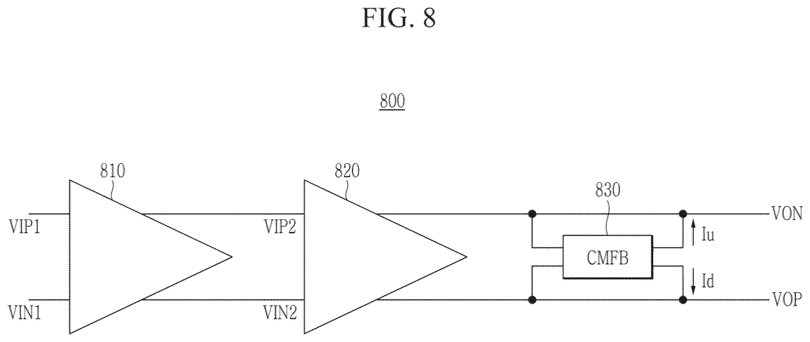

FIG. 8 is a circuit diagram of an additional amplifying circuit according to an embodiment.

Referring to FIG. 8, an amplifying circuit 800 may include a first amplifier 810, a second amplifier 820, and a common mode feedback circuit 830. The first amplifier 810 may receive the first input voltage VIP1 and the second input voltage VIN1, and may output a third input voltage VIN2 and a fourth input voltage VIP2 by amplifying the first input voltage VIP1 and the second input voltage VIN1. In an embodiment, the first input voltage VIP1 and the second input voltage VIN1 may be differential signals having opposite phases, and the third input voltage VIN2 and the fourth input voltage VIP2 may also be differential signals having opposite phases. In addition, the first amplifier 810 may be an inverting amplifier that inverts the phase of the input signal.

In an embodiment, the second amplifier 820 may receive the third input voltage VIN2 and the fourth input voltage VIP2, and may output the first output voltage VOP and the second output voltage VON by amplifying the third input voltage VIN2 and the fourth input voltage VIP2. The first output voltage VOP and the second output voltage VON may be differential signals having opposite phases, and the second amplifier 820 may be an inverting amplifier that inverts the phase of the input signal. As described above, the amplifier that performs 2-stage amplification using the first amplifier 810 and the second amplifier 820 may be referred to as a 2-stage amplifier.

In an embodiment, the common mode feedback circuit 830 may receive the first output voltage VOP and the second output voltage VON, and adjust the first output voltage VOP and the second output voltage VON based on the difference between the reference voltage and the combination of the first output voltage VOP and the second output voltage VON. For example, the common mode feedback circuit 830 may generate the feedback currents Iu and Id to adjust the first output voltage VOP and the second output voltage VON such that the average voltage of the first output voltage VOP and the second output voltage VON becomes approximately equal to the reference voltage.

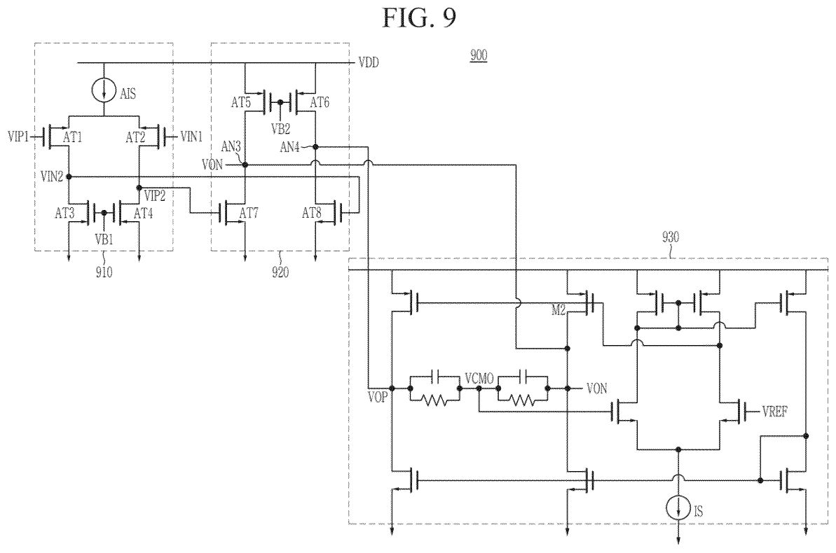

FIG. 9 is a circuit diagram of an additional amplifying circuit according to an embodiment. For convenience, descriptions that are the same as or similar to FIG. 4 to FIG. 8 may be omitted.

In an embodiment, an amplifying circuit 900 may include a first amplifier 910, a second amplifier 920, and a common mode feedback circuit 930. Similar to FIG. 7, the first amplifier 910 may receive the first input voltage VIN1 and the second input voltage VIP1, and may output a third input voltage VIP2 and a fourth input voltage VIN2.

In an embodiment, the second amplifier 920 may include a fifth transistor AT5, a sixth transistor AT6, a seventh transistor AT7, and an eighth transistor AT8. The fifth transistor AT5 may be connected between the supply voltage VDD line and a node AN3. Specifically, the source and drain of the fifth transistor AT5 may be connected to the supply voltage VDD line and the node AN3, respectively. The sixth transistor AT6 may be connected between the supply voltage VDD line and a node AN4. Specifically, the source and drain of the sixth transistor AT6 may be connected to the supply voltage VDD line and the node AN4, respectively. The fifth transistor AT5 and the sixth transistor AT6 may receive a bias voltage VB2 through their gates.

The seventh transistor AT7 may be connected between the node AN3 and the ground voltage VSS line. Specifically, the source and drain of the seventh transistor AT7 may be connected to the node AN3 and the ground voltage VSS line, respectively. The eighth transistor AT8 may be connected between the node AN4 and the ground voltage VSS line. Specifically, the source and drain of the eighth transistor AT8 may be connected to the node AN4 and the ground voltage VSS line, respectively. The seventh transistor AT7 may receive the third input voltage VIP2 through its gate, and the eighth transistor AT8 may receive the fourth input voltage VIN2 through its gate.

In an embodiment, the seventh transistor AT7 may receive the third input voltage VIP2 through its gate, and may adjust the current flowing through the node AN3 based on the third input voltage VIP2. The eighth transistor AT8 may receive the fourth input voltage VIN2 through its gate, and may adjust the current flowing through the node AN4 based on the fourth input voltage VIN2. The node AN3 and the node AN4 may be an output end of the second amplifier 920. In other words, a voltage level of the node AN3 may be output to the common mode feedback circuit 930 as the first output voltage VOP, and a voltage level of the node AN4 may be output to the common mode feedback circuit 930 as the second output voltage VON.

In an embodiment, the fifth transistor AT5 and the sixth transistor AT6 may be implemented as a P-type transistor, and the seventh transistor AT7 and the eighth transistor AT8 may be implemented as a N-type transistor, but is not limited thereto.

In an embodiment, the common mode feedback circuit 930 may generate the common mode output voltage VCMO based on the first output voltage VOP and the second output voltage VON received from the amplifier 920. The common mode feedback circuit 920 may adjust the voltage levels of the first output voltage VOP and the second output voltage VON to ensure that the common mode output voltage VCMO aligns with the reference voltage VREF, based on a comparison between the common mode output voltage VCMO and the reference voltage VREF.

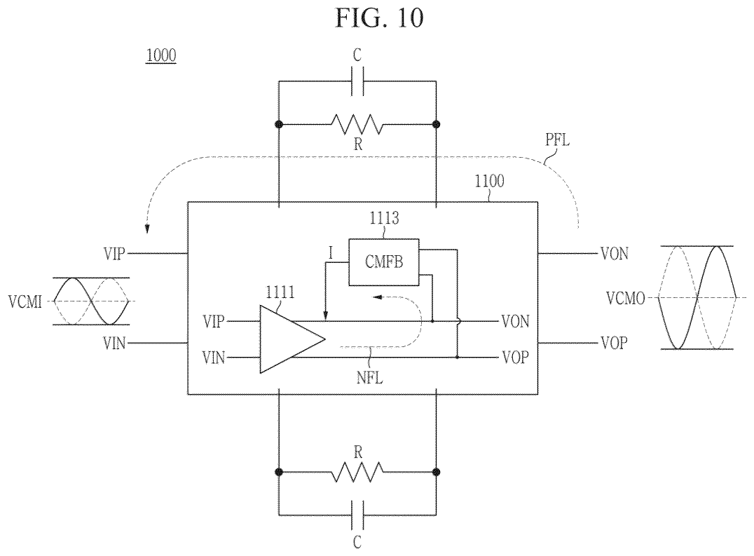

FIG. 10 is a circuit diagram of a filter including an amplifying circuit according to an embodiment.

In an embodiment, a filter 1000 may include an amplifying circuit 1100 for receiving the input voltages VIP and VIN, and the feedback resistor R and the feedback capacitor C connected in parallel to an input end and an output end of the amplifying circuit 1100. The amplifying circuit 1100 may include an amplifier 1111 configured to output the output voltages VON and VOP based on the input voltages VIP and VIN, and a common mode feedback circuit 1113 configured to adjust the voltage levels of the output voltages VON and VOP based on a feedback current I.

The amplifying circuit 1100, the feedback resistor R, and the feedback capacitor C of the filter 1000 may form a positive feedback loop (PFL). When the common mode output voltage VCMO significantly deviates from a predetermined level (e.g., a midpoint between the supply voltage and the ground voltage) due to an unexpectedly large input voltage, a common mode input voltage VCMI may also vary as a result of the positive feedback loop (PFL). Here, the common mode input voltage VCMI corresponds to an average value of the input voltages VIP and VIN. For example, if the common mode output voltage VCMO exceeds a predetermined level due to unexpectedly large the input voltages VIP and VIN, the common mode input voltage VCMI may also increase because of the positive feedback loop (PFL). This can lead to abnormal operations such as amplifier oscillation. To prevent this issue, the gain of a negative feedback loop (NFL) within the amplifying circuit 1100 needs to be maintained greater than the gain of the positive feedback loop (PFL). Meanwhile, the gain of the positive feedback loop (PFL) is determined by the resistance of the feedback resistor R and the capacitance of the feedback capacitor C.

The amplifier 1111 and the common mode feedback circuit 1113 within the amplifying circuit 1100 may form a negative feedback loop (NFL). The voltage levels of the output voltages VON and VOP may be adjusted by the negative feedback loop (NFL). The gain of the negative feedback loop (NFL) may be associated with the range of the common mode output voltage VCMO within which the amplifying circuit 1100 can normally operate. For example, as the operational range of the common mode output voltage VCMO increases, the gain of the negative feedback loop (NFL) may also be increased.

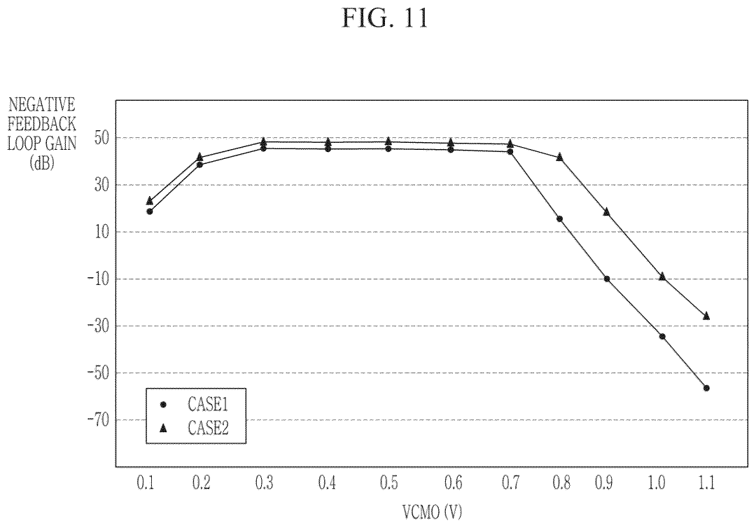

According to an embodiment, the range of the common mode output voltage VCMO within which the amplifying circuit 1100 can normally operate may be expanded. Specifically, the amplifying circuit 1100 may adjust (e.g., pull-up or pull-down) the voltage levels of the output voltages VON and VOP based on the comparison between the common mode output voltage VCMO and the reference voltage, thereby enlarging the operational range of the common mode output voltage VCMO within which the amplifying circuit 1100 can normally operate. Accordingly, the gain of the negative feedback loop (NFL) may also increase. The gain of the negative feedback loop (NFL) within the amplifying circuit 1100 according to an embodiment will be described in detail with reference to the graph of FIG. 11.

FIG. 11 is a graph illustrating changes in the gain of a negative feedback loop according to an embodiment. Specifically, the graph of FIG. 11 shows simulation results, comparing the gain of the negative feedback loop (NFL) in an amplifying circuit with a common mode feedback circuit from a Comparative Example to the gain of the negative feedback loop (NFL) in an amplifying circuit with a common mode feedback circuit according to an embodiment.

A first case CASE1 represents the gain of the negative feedback loop (NFL) in an amplifying circuit with a common mode feedback circuit from a Comparative Example. Specifically, the common mode feedback circuit the first case CASE1 does not include a pull-down circuit. A second case CASE2 represents the gain of the negative feedback loop (NFL) in an amplifying circuit with a common mode feedback circuit according to an embodiment. In this case, the common mode feedback circuit includes a pull-down circuit.

Referring to FIG. 11, as the common mode output voltage VCMO increases, the gain of the negative feedback loop in the second case CASE2 is greater than the gain of the negative feedback loop in the first case CASE1. Specifically, when the common mode output voltage VCMO increases, an amplifying circuit 1110, which includes a common mode feedback circuit according to an embodiment, adjusts the output voltage levels using the pull-down circuit within the common mode feedback circuit. Accordingly, the range of the common mode output voltage VCMO within which the amplifying circuit 1110 can normally operate is expanded. Therefore, when the level of the common mode output voltage VCMO is high, the gain of the negative feedback loop (NFL) within the amplifying circuit 1110 remains greater than the gain of the positive feedback loop (PFL).

According to an embodiment, the gain of the negative feedback loop (NFL) within the filter 1000 may be designed to exceed the gain of the positive feedback loop (PFL). Increasing the gain of the negative feedback loop (NFL) reduces the likelihood of erroneous operation of the amplifying circuit 1110 caused by high input signals and provides the advantage of improving the stability of the amplifying circuit 1110. In other words, the common mode feedback circuit according to an embodiment expands the range of common mode output voltage VCMO within which the amplifying circuit 1110 operates normally and ensures that the gain of the negative feedback loop (NFL) remains higher than the positive feedback loop (PFL), even at high common mode output voltages. This enhances the amplifying circuit's 1110 stability and reduces the likelihood of errors from high input signals.

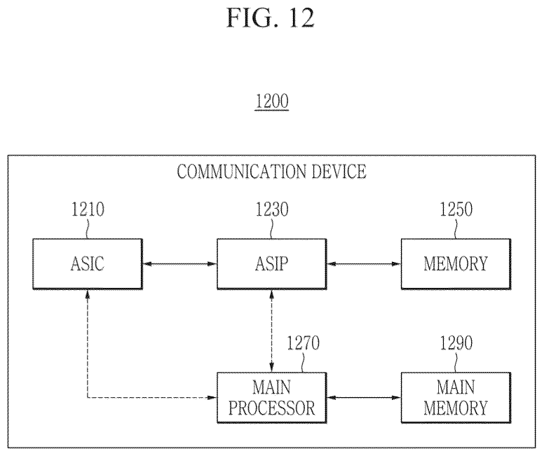

FIG. 12 is a block diagram showing a communication device according to an embodiment.

Referring to FIG. 12, a communication device 1200 may include an application-specific integrated circuit (ASIC) 1210, an application-specific instruction set processor (ASIP) 1230, a memory 1250, a main processor 1270 and a main memory 1290. Two or more among the ASIC 1210, the ASIP 1230 and the main processor 1270 may communicate with each other. In addition, at least two or more among the ASIC 1210, the ASIP 1230, the memory 1250, the main processor 1270 and the main memory 1290 may be embedded in one chip.

The ASIP 1230 may be an integrated circuit customized for a specific purpose, and can support a dedicated instruction set for a specific application and execute instructions included in the instruction set. The memory 1250 may communicate with the ASIP 1230, and may store a plurality of instructions executed by the ASIP 1230, as a non-transitory storage device. For example, the memory 1250 may include any type of memory accessible by the ASIP 1230, such as, as non-limiting examples, a random access memory (RAM), a read-only memory (ROM), a tape, a magnetic disk, an optical disk, a volatile memory, a non-volatile memory, and combination thereof.

The main processor 1270 may control the communication device 1200 by executing the plurality of instructions. For example, the main processor 1270 may control the ASIC 1210 and the ASIP 1230, and may process data received through the wireless communication network or process a user's input with respect to the communication device 1200. The main memory 1290 may communicate with the main processor 1270, and may store the plurality of instructions executed by the main processor 1270, as a non-transitory storage device. For example, the main memory 1290 may include any type of memory accessible by the main processor 1270, such as, as non-limiting examples, a random access memory (RAM), a read-only memory (ROM), a tape, a magnetic disk, an optical disk, a volatile memory, a non-volatile memory, and combination thereof.

The common mode feedback circuit according to the present disclosure and the amplifying circuit including the same described with reference to FIG. 1 to FIG. 11 may be included in all or part of the communication device 1200 of FIG. 12.

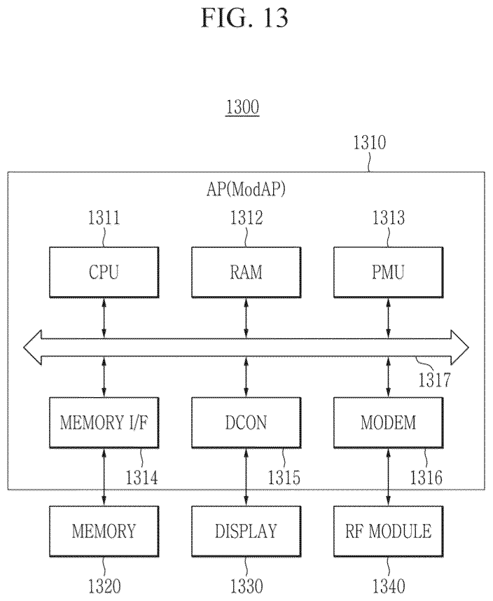

FIG. 13 is a block diagram showing a mobile terminal to which a communication device according to an embodiment is applied.

Referring to FIG. 13, a mobile terminal 1300 may include an application processor 1310 (hereinafter, referred to as AP), a memory 1320, a display 1330 and a radio frequency (RF) module 1340. In addition, the mobile terminal 1300 may further include various other components such as lenses, sensors, and audio modules.

The AP 1310 may be implemented as a system-on-chip (SoC), and may include a central processing unit (CPU) 1311, a RAM 1312, a power management unit (PMU) 1313, a memory interface (I/F) 1314, a display controller (DCON) 1315, a modem 1316 and a bus (system BUS) 1317. The AP 1310 may further include various IPs. The AP 1310 may be referred to as ModAP as the function of a modem chip is integrated therein.

The CPU 1311 may control an overall operation of the AP 1310 and the mobile terminal 1300. The CPU 1311 may control an operation of each component of the AP 1310. In addition, the CPU 1311 may be implemented as a multi-core. The multi-core is one computing component having two or more independent cores.

The RAM 1312 may temporarily store programs, data, or instructions. For example, programs and/or data stored in the memory 1320 may be temporarily stored in the RAM 1312 according to the control or booting code of the CPU 1311. The RAM 1312 may be implemented as DRAM or SRAM.

The PMU 1313 may manage power of each component of the AP 1310. The PMU 1313 may also determine an operating state of each component of the AP 1330 and control an operation thereof.

The memory interface 1314 may control the overall operation of the memory 1320 and control data exchange between each component of the AP 1310 and the memory 1320. The memory interface 1314 can write data to or read data from the memory 1320 according to a request from the CPU 1311.

The display controller 1315 may transmit image data to be displayed on the display 1330 to the display 1330. The display 1300 may be implemented as a flat panel display or a flexible display such as a liquid crystal display (LCD), an organic light emitting diode (OLED), or the like.

For wireless communication, the module 1316 can modulate data to be transmitted to be suitable for the wireless environment and recover the received data. The modem 1316 may perform digital communication with a RF module 2410.

The RF module 1340 may convert a high-frequency signal received through an antenna into a low-frequency signal, and may transmit the converted low-frequency signal to the modem 1316. In addition, the RF module 1340 may convert a low-frequency signal received from the modem 1316 into a high-frequency signal, and may transmit the converted high-frequency signal to an exterior of the mobile terminal 1300 through an antenna. In addition, the RF module 1340 may amplify or filter signals.

For reference, the common mode feedback circuit described above with reference to FIG. 1 to FIG. 11 and the amplification circuit including the same may be implemented in this RF module 1340.

Although embodiments of the present disclosure have been described with reference to practical embodiments, it is to be understood that the disclosure is not limited to the disclosed embodiments. Instead, it is intended to encompass various modifications and equivalent arrangements within the spirit and scope of the appended claims.

What is claimed is:

1. An amplifying circuit, comprising:
an amplifier configured to receive a first input voltage and a second input voltage, and output a first output voltage and a second output voltage by amplifying the first input voltage and the second input voltage; and
a common mode feedback circuit configured to receive the first output voltage through a first node and the second output voltage through a second node, and pull-down or pull-up a voltage level of the first node and a voltage level of the second node based on a magnitude of a feedback voltage based on a difference between a reference voltage and a common mode voltage determined from the first output voltage and the second output voltage.

2. The amplifying circuit of claim 1, wherein the common mode feedback circuit comprises:
a first circuit configured to generate the common mode voltage based on the first output voltage and the second output voltage;
a second circuit configured to generate the feedback voltage based on a difference between the common mode voltage and the reference voltage;
a third circuit configured to pull-up the voltage level of the first node and the voltage level of the second node, such that the common mode voltage has a first voltage level, based on the feedback voltage; and
a fourth circuit configured to pull-down the voltage level of the first node and the voltage level of the second node, such that the common mode voltage has a second voltage level, based on the feedback voltage.

3. The amplifying circuit of claim 2, wherein the third circuit comprises:
a first variable current source connected between a power source voltage line and the first node; and
a second variable current source connected to the power source voltage line and the second node.

4. The amplifying circuit of claim 3, wherein the first voltage level corresponds to a level of the reference voltage.

5. The amplifying circuit of claim 2, wherein the third circuit comprises:
a first transistor connected between a power source voltage line and the first node, and comprising a gate configured to receive the feedback voltage; and
a second transistor connected between the power source voltage line and the second node, and comprising a gate configured to receive the feedback voltage.

6. The amplifying circuit of claim 2, wherein the fourth circuit comprises:
a third variable current source connected to the first node and a ground voltage line; and
a fourth variable current source connected to the second node and the ground voltage line.

7. The amplifying circuit of claim 6, wherein the second voltage level corresponds to a level of the reference voltage.

8. The amplifying circuit of claim 2, wherein the fourth circuit comprises:
a third transistor connected between the first node and a ground voltage line, and comprising a gate configured to receive the feedback voltage; and
a fourth transistor connected between the second node and the ground voltage line, and comprising a gate configured to receive the feedback voltage.

9. The amplifying circuit of claim 2, wherein the second circuit comprises:
a fifth transistor connected between a power source voltage line and a third node;
sixth transistor connected between the power source voltage line and a fourth node;
a seventh transistor connected between the third node and a fifth node, and configured to receive the common mode voltage through its gate;
an eighth transistor connected between the fourth node and the fifth node, and configured to receive the reference voltage through its gate;
a ninth transistor connected between the power source voltage line and a sixth node, and configured to receive a voltage of the third node through its gate;
a tenth transistor connected between the sixth node and a ground voltage line, and configured to receive a voltage of the sixth node through its gate; and
a current source connected between the fifth node and the ground voltage line.

10. The amplifying circuit of claim 9, wherein the second circuit is configured to output a voltage of the fourth node as the feedback voltage to the third circuit when the common mode voltage is lower than the reference voltage, and output the voltage of the sixth node as the feedback voltage to the fourth circuit when the common mode voltage is higher than the reference voltage.

11. The amplifying circuit of claim 1, wherein the amplifier comprises:
a first amplifier configured to receive the first input voltage and the second input voltage, and output a third input voltage and a fourth input voltage by amplifying the first input voltage and the second input voltage; and
a second amplifier configured to receive the third input voltage and the fourth input voltage, and output the first output voltage and the second output voltage by amplifying the third input voltage and the fourth input voltage.

12. An amplifying circuit, comprising:
a first circuit configured to receive a first voltage through a first node, receive a second voltage through a second node, and output a common mode voltage based on the first voltage and the second voltage;
a second circuit configured to generate a feedback voltage based on the common mode voltage and a reference voltage; and
a third circuit connected to the first node and the second node, and configured to adjust levels of the first voltage and the second voltage based on the feedback voltage.

13. The amplifying circuit of claim 12, wherein the third circuit comprises:
a first transistor connected between a power source voltage line and the first node, and comprising a gate configured to receive the feedback voltage;
a second transistor connected between the power source voltage line and the second node, and comprising a gate configured to receive the feedback voltage;
a third transistor connected between the first node and a ground voltage line, and comprising a gate configured to receive the feedback voltage; and
a fourth transistor connected between the second node and the ground voltage line, and comprising a gate configured to receive the feedback voltage.

14. The amplifying circuit of claim 13, wherein the second circuit is configured to output a voltage of a first level as the feedback voltage to the first transistor and the second transistor when a common mode output voltage is lower than the reference voltage, and output a voltage of a second level, which is different from the first level, as the feedback voltage to the third transistor and the fourth transistor when the common mode output voltage is higher than the reference voltage.

15. The amplifying circuit of claim 13, wherein the second circuit comprises:
a fifth transistor connected between the power source voltage line and a third node;
a sixth transistor connected between the power source voltage line and a fourth node;
a seventh transistor connected between the third node and a fifth node, and configured to receive a common mode output voltage through its gate;
an eighth transistor connected between the fourth node and the fifth node, and configured to receive the reference voltage through its gate;
a ninth transistor connected between the power source voltage line and a sixth node, and configured to receive a voltage of the third node through its gate;
a tenth transistor connected between the sixth node and the ground voltage line, and configured to receive a voltage of the sixth node through its gate; and
a current source connected between the fifth node and the ground voltage.

16. The amplifying circuit of claim 12, further comprising an amplifier configured to receive a first input voltage and a second input voltage, and output the first voltage and the second voltage by amplifying the first input voltage and the second input voltage.

17. The amplifying circuit of claim 16, wherein the amplifier comprises:
a current source connected between a power source voltage line and a third node;
a first transistor connected between the first node and the third node, and comprising a gate configured to receive the first input voltage;
a second transistor connected between the second node and the third node, and comprising a gate configured to receive the second input voltage;
a third transistor connected between the first node and a ground voltage line, and comprising a gate configured to receive a bias voltage; and
a fourth transistor connected between the second node and the ground voltage line, and comprising a gate configured to receive the bias voltage.

18. The amplifying circuit of claim 16, wherein the amplifier comprises:
a first amplifier configured to receive the first input voltage and the second input voltage, and output a third input voltage and a fourth input voltage by amplifying the first input voltage and the second input voltage; and
a second amplifier configured to receive the third input voltage and the fourth input voltage, and output the first voltage and the second voltage by amplifying the third input voltage and the fourth input voltage.

19. A radio frequency (RF) circuit, comprising:
a transmission filter configured to filter a first transmission signal input from an external device;
a transmission mixer configured to receive the filtered first transmission signal, upconvert a frequency of the filtered first transmission signal, and output a second transmission signal; and
a power amplifier configured to receive the second transmission signal, and amplify the second transmission signal,
wherein the transmission filter comprises an amplifier configured to receive the first transmission signal and a second signal whose phase is inverted from the first transmission signal, and output a first output signal and a second output signal by amplifying the first transmission signal and the second signal, and a common mode feedback circuit configured to receive the first output signal through a first node, receive the second output signal through a second node, generate a feedback current based on a reference voltage and a common mode voltage that is based on the first output signal and the second output signal, and adjust a voltage level of the first node and a voltage level of the second node according to the feedback current.

20. The RF circuit of claim 19, wherein the common mode feedback circuit is configured to increase the feedback current for pulling-up a voltage of the first node and a voltage of the second node when the common mode voltage is lower than the reference voltage to raise voltage levels of the first output signal and the second output signal, and increase the feedback current for pulling-down the voltage of the first node and the voltage of the second node to lower the voltage levels of the first output signal and the second output signal when the common mode voltage is higher than the reference voltage.
